(19) United States
(12) Patent Application Publication
(10) Pub. No.: US 2026/0188612 A1
(43) Pub. Date: Jul. 2, 2026

(54) CHARGED PARTICLE BEAM WRITING METHOD, CHARGED PARTICLE BEAM WRITING APPARATUS AND COMPUTER READABLE RECORDING MEDIUM

(71) Applicant: NuFlare Technology, Inc., Yokohama-shi (JP)

(72) Inventors: Kenta FUKUOKA, Yokohama-shi (JP); Kenichi YASUI, Kawasaki-shi (JP)

(73) Assignee: NuFlare Technology, Inc., Yokohama-shi (JP)

(21) Appl. No.: 19/413,182

(22) Filed: Dec. 9, 2025

(30) Foreign Application Priority Data
Dec. 27, 2024 (JP) 2024-232750
Oct. 14, 2025 (JP) 2025-172995

(51) Int. Cl. H01J 37/302; H01J 37/317

(52) U.S. Cl. CPC H01J 37/3026; H01J 37/3174; H01J 2237/31764

(57) ABSTRACT

In one embodiment, a charged particle beam writing method calculates an irradiation amount of a charged particle beam for writing a pattern on a substrate with a target mesh size based on design data. The writing region is virtually divided into first mesh regions using a mesh size larger than the target size, and an area density of the pattern in each first mesh region is calculated. A first irradiation amount of individual beams, defined at grid intersections of a control grid in the writing region, is then calculated using the area density. A second irradiation amount for the individual beams, when the writing region is divided with the target mesh size, is obtained from the first irradiation amount using a conversion formula including a reduction ratio of the target mesh size with respect to the predetermined mesh size.

### CROSS REFERENCE TO RELATED APPLICATION

This application is based upon and claims benefit of priority from the Japanese Patent Application No. 2024-232750, filed on Dec. 27, 2024, the entire contents of which are incorporated herein by reference.

### FIELD

The present invention relates to a charged particle beam writing method, a charged particle beam writing apparatus and a computer readable recording medium.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

For example, there is a writing apparatus using a multi-beam. As compared to when writing is performed with a single electron beam, use of a multi-beam allows many beams to be emitted at a time, thus the throughput can be significantly improved. In a multi-beam writing apparatus, for example, an electron beam emitted from an electron source is passed through a shaping aperture array substrate having multiple openings to form a multi-beam, and each beam is individually blanking-controlled. The beams that are not blocked are reduced by an optical system, deflected by a deflector, and irradiated onto desired positions on a sample.

In the multi-beam writing apparatus, a sample surface is virtually divided into mesh pattern to generate a plurality of mesh regions, and the areal density of the pattern disposed inside each mesh region is calculated. Then, based on the areal density, the irradiation amount of each beam in a multi-beam is calculated.

The resolution can be improved by reducing the size (mesh size) of the mesh regions used to calculate the areal density. However, when the mesh size is reduced, a problem arises in that a longer processing time is taken due to an increase in the amount of calculation, and data transfer and saving in memory becomes difficult due to an increase in the data volume of a calculation result.

### BRIEF DESCRIPTION OF THE DRAWINGS

FIG. 1 is a schematic view of a multi-charged particle beam writing apparatus according to an embodiment of the present invention.

FIG. 2 is a plan view of a shaping aperture array member.

FIG. 3 is a view for explaining an example of a writing operation.

FIG. 4 is a view for explaining rasterize processing.

FIG. 5 is a view illustrating an example of control grids.

FIG. 6 is a view illustrating a relationship between mesh size and pattern areal density.

FIG. 7 is a graph illustrating an irradiation amount conversion formula.

FIG. 8 is a flowchart for explaining a writing method according to the embodiment.

FIG. 9A is a view illustrating a simulation result of a pattern which is written without performing irradiation amount conversion, and FIG. 9B is a view illustrating a simulation result of a pattern written by performing irradiation amount conversion.

FIG. 10 is a graph illustrating an irradiation amount conversion formula according to a variation.

FIG. 11 is a graph illustrating an irradiation amount conversion formula according to a variation.

FIGS. 12A to 12C are diagrams illustrating simulation results of patterns written by performing irradiation amount conversion.

### DETAILED DESCRIPTION

In one embodiment, a charged particle beam writing method is for calculating an irradiation amount of a charged particle beam needed to write a figure pattern on a writing region of a substrate with a target mesh size based on design data, and writing the figure pattern with the target mesh size. The charged particle beam writing method includes virtually dividing the writing region, on which the figure pattern is to be written, into a plurality of first mesh regions using a predetermined mesh size larger than the target mesh size, calculating an areal density of the figure pattern disposed in each of the first mesh regions, calculating, by using the areal density, a first irradiation amount of an individual beam at irradiation positions corresponding to grid intersection points of control grids provided in the writing region, determining, by using the first irradiation amount and a conversion formula including a reduction ratio of the target mesh size with respect to the predetermined mesh size, a second irradiation amount of the individual beam when the writing region is virtually divided with the target mesh size, and irradiating the substrate with the charged particle beam based on the second irradiation amount, and writing the figure pattern on the substrate.

In the following embodiments, a configuration using an electron beam will be described as an example of a charged particle beam. However, the charged particle beam is not limited to the electron beam and may be a beam using charged particles such as an ion beam.

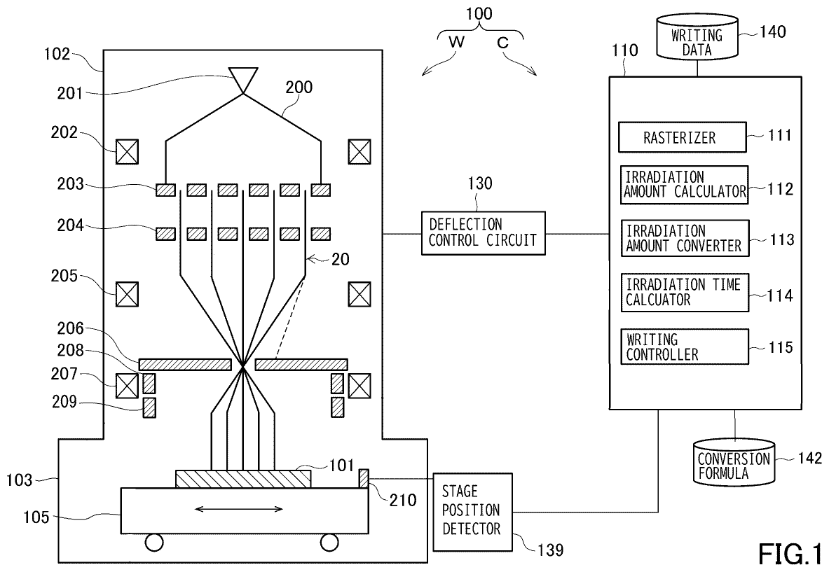

FIG. 1 is a schematic configuration view of a writing apparatus according to an embodiment. As illustrated in FIG. 1, a writing apparatus 100 includes a writer W and a controller C. The writing apparatus 100 is an example of a multi-charged particle beam writing apparatus. The writer W includes an electron optical column 102 and a writing chamber 103. In the electron optical column 102, an electron source 201, an illumination lens 202, a shaping aperture array substrate 203, a blanking aperture array substrate 204, a reduction lens 205, a limiting aperture member 206, an objective lens 207, and deflectors 208 and 209 are disposed to constitute a multi-beam generation mechanism.

An XY stage 105 is disposed in the writing chamber 103. A substrate 101 as a writing target is disposed on the XY stage 105. The substrate 101 is e.g., a mask blank or a semiconductor substrate (silicon wafer). In addition, a mirror 210 for position measurement is disposed on the XY stage 105.

The controller C includes a control computer 110, a deflection control circuit 130, a stage position detector 139, storage 140 and storage 142. Writing data is input to the storage 140 from the outside, and stored therein. In the writing data, information on a plurality of figure patterns to be written is normally defined. Specifically, for each figure pattern, the figure code, coordinates, and size are defined.

The control computer 110 includes a rasterizer 111, an irradiation amount calculator 112, an irradiation amount converter 113, an irradiation time calculator 114 and a writing controller 115. Each component of the control computer 110 may be composed of hardware such as an electric circuit, or composed of software such as a program that executes these functions. When each component is comprised of software, a program implementing at least part of the functions of the control computer 110 may be stored in a recording medium such as a flexible disk and a CD-ROM to cause a computer to read and execute the program.

The stage position detector 139 emits a laser, receives light reflected from the mirror 210, and detects the position of the XY stage 105 by laser interferometry.

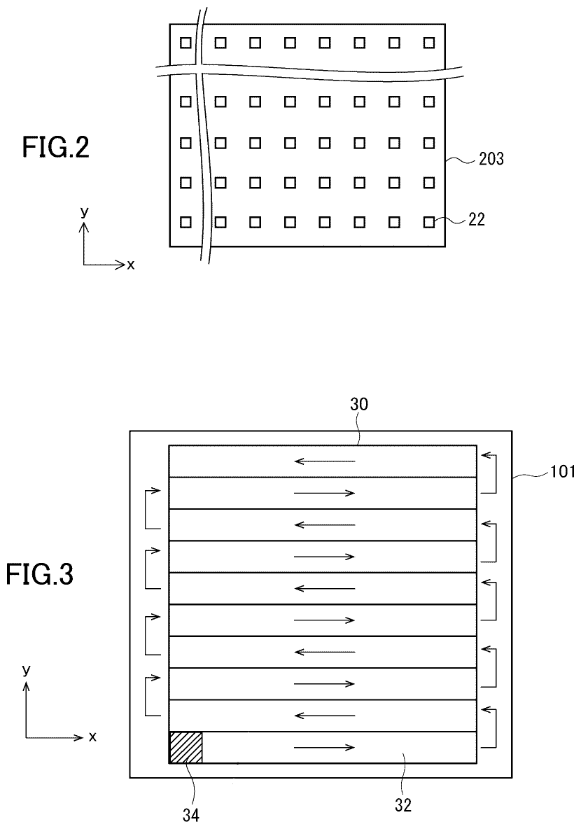

FIG. 2 is a conceptual view illustrating the configuration of the shaping aperture array substrate 203. As illustrated in FIG. 2, in the shaping aperture array substrate 203, openings 22 in m vertical (y direction) columns×n horizontal (x direction) rows (m, n≥2) are formed with a predetermined arrangement pitch. The openings 22 are formed in rectangular or circular shapes having the same dimensions.

An electron beam 200 emitted from the electron source 201 illuminates the entire shaping aperture array substrate 203 substantially perpendicularly by the illumination lens 202. The electron beam 200 illuminates an area including the plurality of openings 22. The electron beam 200 passes through the plurality of openings 22 of the shaping aperture array substrate 203, thereby forming a multi-beam 20 having e.g., a beam array in a rectangular shape.

In the blanking aperture array substrate 204, passage holes are formed corresponding to the arrangement positions of the openings 22 of the shaping aperture array substrate 203. A set (blanker) of two electrodes forming a pair is disposed in each passage hole. The multi-beam 20 passes through corresponding passage holes of the blanking aperture array substrate 204.

The electron beam passing through each passage hole is independently controlled for each beam in a beam-ON or beam-OFF state by a voltage applied to a corresponding blanker. In a beam-ON state, the opposed electrodes of a blanker are controlled at the same potential, and the blanker does not deflect the beam. In a beam-OFF state, the opposed electrodes of a blanker are controlled at different potentials, and the blanker deflects the beam. In this manner, multiple blankers perform blanking deflection on corresponding beams in the multi-beam which has passed through the plurality of openings 22 of the shaping aperture array substrate 203.

The multi-beam 20 which has passed through the blanking aperture array substrate 204 is reduced by the reduction lens 205, and ideally passes through the same point on the limiting aperture member 206 with all beams in an ON state. The trajectory of the beam is adjusted by an alignment coil which is not illustrated so that the above-mentioned point is located in the opening in the center of the limiting aperture member 206.

Each beam controlled in a beam-OFF state is deflected by a blanker of the blanking aperture array substrate 204, and passes through a trajectory deviated from the opening of the limiting aperture member 206, thus is blocked by the limiting aperture member 206. In contrast, each beam controlled in a beam-ON state is not deflected by a blanker, thus passes through the opening of the limiting aperture member 206. In this manner, ON/OFF of the beam is controlled by the blanking control of the blanking aperture array substrate 204.

The limiting aperture member 206 blocks each beam which is deflected to achieve a beam-OFF state by multiple blankers. The multi-beam for one shot is formed by the beam which has passed through the limiting aperture member 206 since beam-ON until beam-OFF is achieved.

The multi-beam 20 which has passed through the limiting aperture member 206 is focused by the objective lens 207, and is projected on the substrate 101 with a desired reduction ratio. The deflectors 208, 209 each deflect the entire multi-beam in the same direction by the same distance. The deflection amounts of the deflectors 208, 209 are independently controlled. The irradiation position of the multi-beam on the substrate 101 is controlled by the deflectors 208, 209.

During writing, the XY stage 105 is controlled to be moved continuously at a constant speed. The irradiation position of the beam is then controlled by the deflector 208 so that the irradiation position follows the movement of the XY stage 105. The multi-beam emitted simultaneously is ideally arranged with the pitch which is the product of the arrangement pitch of the plurality of openings 22 of the shaping aperture array substrate 203 and the above-mentioned desired reduction ratio. During writing, the position control by deflection causes the multi-beam 20 to perform a writing operation by a raster scan method for exposing all pixels defined on the substrate 101. When the beam is incident on a pixel including no pattern, the beam is controlled in a beam-OFF state by the blanking control.

FIG. 3 is a conceptual view for explaining the writing operation. As illustrated in FIG. 3, a writing region 30 on the substrate 101 is virtually divided into e.g., a plurality of stripe-shaped regions 32 with a predetermined width in y direction (a first direction). When writing is performed on these stripe regions, the XY stage 105 is first moved, and an irradiation region (beam array) 34 which can be irradiated with the multi-beam at one time is adjusted to be located at the left end of the first stripe region 32, then writing is started.

When writing is performed on the first stripe region 32, the XY stage 105 is moved continuously in −x direction at a constant speed, thus writing is performed on the substrate 101 relatively in +x direction. After the writing on the first stripe region 32 is completed, the XY stage 105 is stopped. Next, the stage position is moved in −y direction by the stripe width, and the beam array 34 is adjusted to be located at the right end of the second stripe region 32. Subsequently, the XY stage 105 is moved continuously in +x direction at a constant speed, thus writing is performed on the substrate 101 in −x direction.

On the third stripe region 32, writing is performed in +x direction, and on the fourth stripe region 32, writing is performed in −x direction. Writing may be performed on each stripe region 32 in the same direction; however, in this case, after writing is performed, an operation of returning the stage position is added, thus the writing time increases.

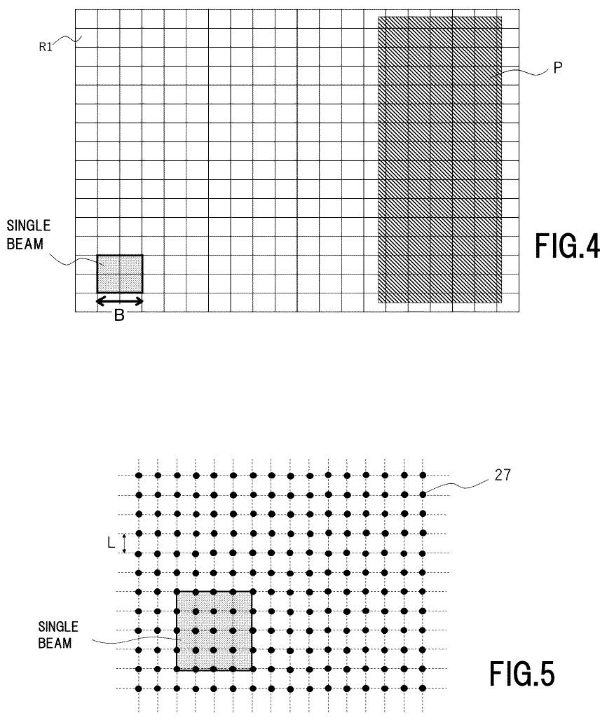

In multi-beam writing, rasterization processing is performed, and as illustrated in FIG. 4, the surface of the substrate 101 is virtually divided into a mesh pattern to generate a plurality of mesh regions R1, and for each mesh region R1, the areal density of the figure pattern P disposed inside the mesh region R1 is calculated. Hereinafter, the size (the length of one side) of each mesh region is referred to as the mesh size.

Also, in multi-beam writing, as illustrated in FIG. 5, control grids having lattice pattern set on the surface of the substrate 101, and grid intersection points 27 provide the irradiation positions of the beams (individual beams) in the multi-beam. The irradiation positions are reference positions which are irradiated with respective beams, and the center of each emitted beam is not necessarily a grid intersection point. Hereinafter, the interval between the control grids is referred to as a grid size L. The grid size L is any size which is controllable as the deflection position of the deflector 209. The grid size L is preferably small in accuracy wise, and may be 1/N (N is a natural number) of the mesh size.

An irradiation amount of the individual beam is assigned to each grid intersection point 27. The irradiation amount is calculated based on the areal density of each mesh region R1.

For example, the mesh size is smaller than or equal to the beam size (the size of one side of the individual beam on the surface of the substrate 101) of the individual beam. FIG. 4 illustrates an example in which the mesh size is ½ of a beam size B.

FIG. 5 illustrates an example in which the grid size L is ¼ of the beam size B. When the grid size L is B/4, 16 grid intersection points 27 are disposed in the region of one individual beam. Specifically, when each grid intersection point 27 is irradiated with a beam, the same region on the surface of the substrate 101 is irradiated 16 times, thus multiple writing is performed with a multiplicity of 16. It is not always necessary to irradiate all the grid intersection points, and a method of irradiating part of the grid intersection points may be adopted.

The irradiation amount assigned to each grid intersection point 27 is calculated based on the areal density of the mesh region R1 in which the grid intersection point 27 is located.

The writing resolution can be improved by reducing the mesh size; however, the amount of calculation increases. For example, when the mesh size is reduced to ½, the number of mesh regions R1 is quadrupled, thus the amount of calculation of areal density increases. Also, the data volume of the calculation result increases, and transfer and saving of the calculation result becomes difficult.

The present embodiment achieves a resolution comparable to the resolution when the areal density is calculated with a small mesh size, while reducing the increase in the amount of calculation.

In the present embodiment, the rasterization processing is first performed with a large mesh size, the areal density for each mesh region is calculated, and a first irradiation amount of the beam corresponding to each grid intersection point 27 is calculated using the calculated areal density. The first irradiation amount is substituted into a predetermined conversion formula, and converted to a second irradiation amount which is equivalent to the irradiation amount based on the areal density calculated with a small mesh size (target mesh size).

The first irradiation amount and the second irradiation amount are values in proportion to the areal density, thus can be normalized to the range of 0 to 1 and treated.

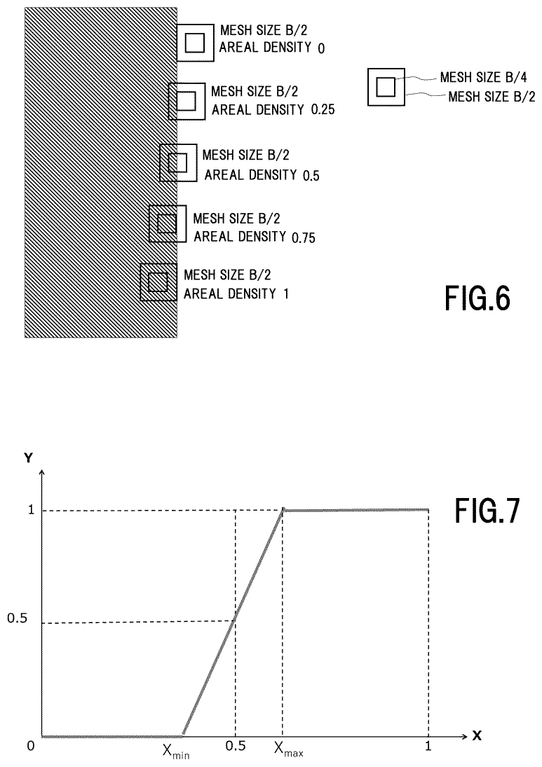

FIG. 6 illustrates a relationship with pattern areal density when the mesh size is B/2 and when the mesh size is B/4.

When the mesh size is B/2 and the pattern areal density is from 0 to 0.25, the pattern areal density can be considered 0 at the mesh size of B/4.

When the mesh size is B/2 and the pattern areal density is in a range of 0.25 to 0.75, the pattern areal density with the mesh size B/4 increases in proportion to increase in pattern areal density with the mesh size B/2. When the mesh size is B/2 and the pattern areal density is 0.5, the pattern areal density with the mesh size B/4 also can be considered 0.5. When the mesh size is B/2 and the pattern areal density is 0.75, the pattern areal density with the mesh size B/4 can be considered 1.

When the mesh size is B/2 and the pattern areal density is from 0.75 to 1, the pattern areal density at mesh size B/4 can be considered 1.

Specifically, using the conversion formula Y=F(X) as shown in FIG. 7, the first irradiation amount X based on the areal density with the mesh size B/2 can be converted to a second irradiation amount Y which is equivalent to the irradiation amount based on the areal density with the mesh size B/4 (target mesh size).

In the range of 0≤X≤Xₘᵢₙ, Y=0 (slope is 0), and in the range of Xₘₐₓ≤X≤1, Y=1 (slope is 0). Let A be the reduction ratio of mesh size due to the conversion, Xₘᵢₙ=0.5 (1−A), and Xₘₐₓ=0.5 (1+A). For example, when the mesh size B/2 is reduced to the mesh size B/4, the reduction ratio A=½.

In the range of Xₘᵢₙ<X<Xₘₐₓ, the conversion formula is Y=(X−0.5)/A+0.5. The slope of the graph in the range of Xₘᵢₙ<X<Xₘₐₓ is the reciprocal of the reduction ratio A.

The first irradiation amount X calculated using the areal density of the mesh region with a large mesh size is substituted into such conversion formula, thus it is possible to obtain the second irradiation amount Y equivalent to the irradiation amount based on the areal density calculated with a small mesh size. What's needed is just conversion of the irradiation amount using the conversion formula, an increase in the amount of calculation can be reduced, as compared to when the areal density of each mesh region is calculated with a small mesh size.

The storage 142 stores the data of such conversion formula.

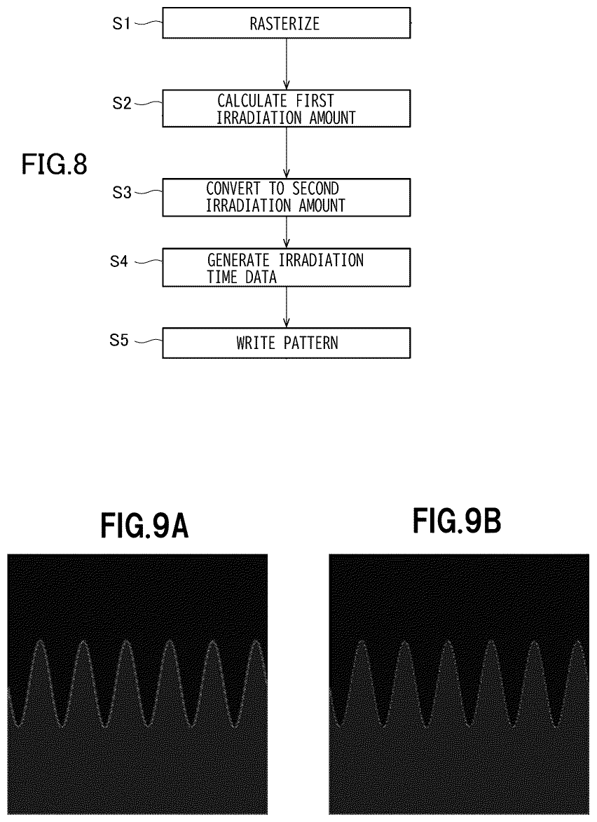

Next, the writing method according to the embodiment will be described based on the flowchart illustrated in FIG. 8.

The rasterizer 111 reads writing data from the storage 140, and performs rasterization processing (step S1). Specifically, the writing region 30 of the substrate 101 is mesh-divided with a predetermined first mesh size to generate mesh regions R1, and for each mesh region R1, the areal density of the figure pattern disposed inside the mesh region R1 is calculated. The first mesh size is smaller than or equal to the beam size B of each individual beam in the multi-beam 20, and is, for example, B/2 (½ of the beam size). When the shape of the individual beam is a square, the beam size B is the length of each side, and when the shape of the individual beam is a circle, the beam size B is the diameter.

The irradiation amount calculator 112 sets control grids in the writing region 30 of the substrate 101 with a predetermined grid size, and for each grid intersection point 27, calculates the first irradiation amount of the individual beam at the irradiation position of the grid intersection point 27 (step S2). The grid size is smaller than the first mesh size of the mesh division in step S1, and is, for example, B/4 (¼ of the beam size).

For example, the irradiation amount calculator 112 calculates the first irradiation amount by multiplying the areal density of the mesh region R1 in which the grid intersection point 27 is located by a predetermined reference irradiation amount.

The irradiation amount converter 113 reads a conversion formula from the storage 142, and substitutes the first irradiation amount X (the value in the range of 0 to 1, obtained by dividing the first irradiation amount by the reference irradiation amount) calculated in step S2 into the conversion formula to convert the first irradiation amount X to a second irradiation amount Y (step S3). The second irradiation amount Y is the value equivalent to the irradiation amount calculated when the rasterization processing is performed with a second mesh size smaller than the first mesh size.

The irradiation time calculator 114 multiplies the second irradiation amount Y (the value obtained by multiplying the second irradiation amount after the conversion by a reference irradiation amount) by a proximity effect correction factor to determine the incident irradiation amount of beam at each grid intersection point 27, divides the incident irradiation amount by the beam current to generate irradiation time data, and transfers the irradiation time data to the deflection control circuit 130 (step S4). The deflection control circuit 130 controls the ON/OFF states of each blanker of the blanking aperture array substrate 204 based on the irradiation time data, and writes a pattern on the substrate 101 (step S5).

FIG. 9A illustrates a simulation result of a pattern to be written when the rasterization processing is performed on a sine wave pattern with the mesh size B/2, the irradiation amount of each beam is determined with the grid size B/4, and the irradiation amount conversion is not applied.

FIG. 9B illustrates a simulation result of a pattern to be written when the rasterization processing is performed on the same sine wave pattern with the mesh size B/2, the irradiation amount of each beam is determined with the grid size B/4, and the irradiation amount is converted by the conversion formula with a reduction ratio of ½.

It is seen that a more favorable resolution can be achieved by performing the rasterization processing with the mesh size B/2 and converting the irradiation amount by the conversion formula with a reduction ratio of ½, as compared to when the rasterize processing is performed with the mesh size B/2, and the irradiation amount is not converted.

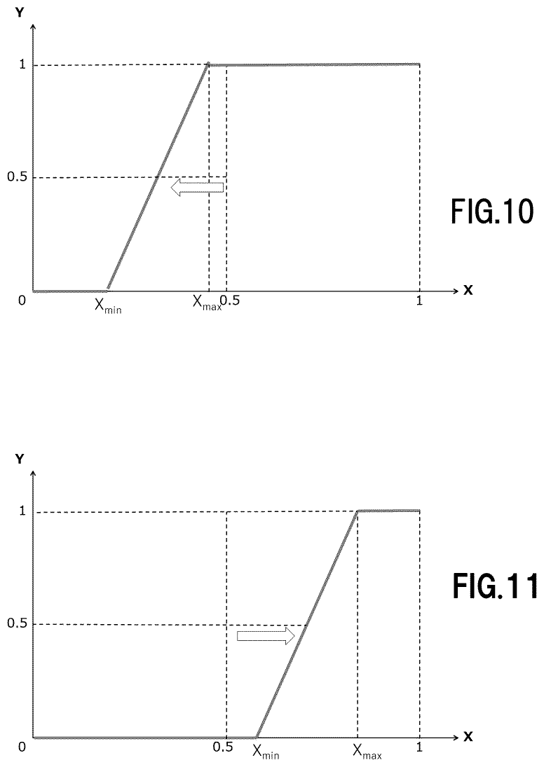

The conversion formula illustrated in FIG. 7 passes through the point at X=0.5, Y=0.5, and as illustrated in FIG. 10, resize processing to enlarge the pattern can be added by reducing Xₘᵢₙ and Xₘₐₓ, that is, by shifting the range of Xₘᵢₙ<X<Xₘₐₓ toward the negative direction.

As illustrated in FIG. 11, resize processing to reduce the pattern can be added by increasing Xₘᵢₙ and Xₘₐₓ, namely, by shifting the range of Xₘᵢₙ<X<Xₘₐₓ toward the positive direction.

When resize processing is performed together, let Resize be the amount of resize, and Mesh be the mesh size of the rasterization processing, then Xₘᵢₙ, Xₘₐₓ can be represented by the following expressions. Note that the settable amount of resize is the value smaller than the mesh size, that is, |Resize|<Mesh.

$${X}_{min} = 0.5 ( 1 - \frac{Resize}{Mesh} - A )$$

$${X}_{max} = 0.5 ( 1 - \frac{Resize}{Mesh} + A )$$

The conversion formula is as follows.

$$\begin{matrix}X \leq {X}_{min} & Y = 0 \\ {X}_{min} < X < {X}_{max} & Y = \frac{1}{A} \{ X - 0.5 ( 1 - \frac{Resize}{Mesh} ) \} + 0.5 \\ X \geq {X}_{max} & Y = 1\end{matrix}$$

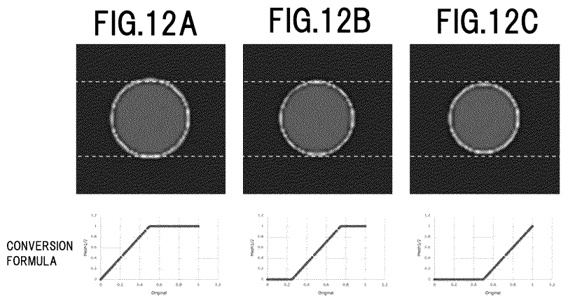

FIG. 12A illustrates a simulation result of a pattern to be written when the rasterization processing is performed on a circular pattern with the mesh size B/2, the irradiation amount of each beam is determined with the grid size B/4, and the irradiation amount is converted by a conversion formula with a reduction ratio of ½, the conversion formula including resize processing to enlarge the pattern.

FIG. 12B illustrates a simulation result of a pattern to be written when the rasterization processing is performed on a circular pattern with the mesh size B/2, the irradiation amount of each beam is determined with the grid size B/4, and the irradiation amount is converted by a conversion formula with a reduction ratio of ½.

FIG. 12C illustrates a simulation result of a pattern to be written when the rasterization processing is performed on a circular pattern with the mesh size B/2, the irradiation amount of each beam is determined with the grid size B/4, and the irradiation amount is converted by a conversion formula with a reduction ratio of ½, the conversion formula including resize processing to reduce the pattern.

It is seen that the resize processing can be performed on a writing pattern by including a term (offset amount) of the resize processing in the conversion formula.

The conversion formula Y=F(X) illustrated in FIG. 7 includes a range in which the slope is 0, and a range in which the slope is higher than 1, and when Y=F(X) is displayed in a graph, the graph is a combination of straight lines; however, as long as Y=F(0)=0 and Y=F(1)=1 are satisfied, a curve may be included for at least part of the range of 0<X<1.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam writing method for calculating an irradiation amount of a charged particle beam needed to write a figure pattern on a writing region of a substrate with a target mesh size based on design data, and writing the figure pattern with the target mesh size, the charged particle beam writing method comprising:
virtually dividing the writing region, on which the figure pattern is to be written, into a plurality of first mesh regions using a predetermined mesh size larger than the target mesh size;
calculating an areal density of the figure pattern disposed in each of the first mesh regions;
calculating, by using the areal density, a first irradiation amount of an individual beam at irradiation positions corresponding to grid intersection points of control grids provided in the writing region;
determining, by using the first irradiation amount and a conversion formula including a reduction ratio of the target mesh size with respect to the predetermined mesh size, a second irradiation amount of the individual beam when the writing region is virtually divided with the target mesh size; and
irradiating the substrate with the charged particle beam based on the second irradiation amount, and writing the figure pattern on the substrate.

2. The charged particle beam writing method according to claim 1,
wherein the conversion formula further includes a resize amount of the figure pattern, and the second irradiation amount is an irradiation amount of the individual beam for resizing the figure pattern.

3. The charged particle beam writing method according to claim 1,
wherein the predetermined mesh size is equal to or smaller than the size of the individual beam.

4. The charged particle beam writing method according to claim 1,
wherein the conversion formula is represented by a function Y=F(X) where X is the first irradiation amount, and Y is the second irradiation amount, and the function Y=F(X) includes a range in which a slope is 0, and a range in which the slope is a predetermined value higher than 1 according to the first irradiation amount.

5. The charged particle beam writing method according to claim 1,
wherein the conversion formula is represented by a function Y=F(X) where X is the first irradiation amount, and Y is the second irradiation amount, and when X and Y in the function Y=F(X) are normalized to a range from 0 to 1, Y=F(0)=0 and Y=F(1)=1 are satisfied.

6. A charged particle beam writing apparatus for calculating an irradiation amount of a charged particle beam needed to write a figure pattern on a writing region of a substrate with a target mesh size based on design data, and writing the figure pattern with the target mesh size, the charged particle beam writing apparatus comprising:
a rasterizer that generates a plurality of first mesh regions by virtually dividing, with a predetermined mesh size larger than the target mesh size, the writing region on which the figure pattern is written by irradiating the substrate with a charged particle beam, and that calculates an areal density of the figure pattern disposed in each of the first mesh regions;
a calculator that calculates, by using the areal density, a first irradiation amount of an individual beam at irradiation positions which are grid intersection points of control grids provided in the writing region;
a converter that determines, by using the first irradiation amount and a conversion formula including a reduction ratio of the target mesh size with respect to the predetermined mesh size, a second irradiation amount of the individual beam when the writing region is virtually divided with the target mesh size; and
a writer that irradiates the substrate with the charged particle beam based on the second irradiation amount, and writes the figure pattern on the substrate.

7. A non-transitory computer readable medium storing a program that causes a computer to execute a process for calculating an irradiation amount of a charged particle beam needed to write a figure pattern on a writing region of a substrate with a target mesh size based on design data, and writing the figure pattern with the target mesh size, the process comprising the steps of:
generating a plurality of first mesh regions by virtually dividing, with a predetermined mesh size larger than the target mesh size, the writing region on which the figure pattern is written;
calculating an areal density of the figure pattern disposed in each of the first mesh regions;
calculating, by using the areal density, a first irradiation amount of an individual beam at irradiation positions which are grid intersection points of control grids provided in the writing region;
determining, by using the first irradiation amount and a conversion formula including a reduction ratio of the target mesh size with respect to the predetermined mesh size, a second irradiation amount of the individual beam when the writing region is virtually divided with the target mesh size; and
irradiating the substrate with the charged particle beam based on the second irradiation amount, and controlling the writing apparatus so as to write the figure pattern on the substrate.
